(19) United States
(12) Patent Application Publication
(10) Pub. No.: US 2025/0300055 A1
(43) Pub. Date: Sep. 25, 2025

(54) APPARATUS WITH ELECTRICAL INTERCONNECT

(71) Applicant: Cisco Technology, Inc., San Jose, CA (US)

(72) Inventors: D. Brice ACHKIR, Livermore, CA (US); Mark C. NOWELL, Ottawa (CA)

(21) Appl. No.: 19/011,501

(22) Filed: Jan. 6, 2025

Related U.S. Application Data
(60) Provisional application No. 63/568,309, filed on Mar. 21, 2024.

(51) Int. Cl. H01L 23/498; H01L 21/48

(52) U.S. Cl. CPC H01L 23/49833; H01L 21/4857; H01L 23/49838

(57) ABSTRACT

An apparatus having at least one interconnect is provided. In one aspect, an apparatus includes a first media providing a first signal channel, a second media providing a second signal channel, and an interconnect. The interconnect includes a first mating structure that includes a first electrode mounted to the first media and a thin film dielectric disposed on the first electrode. The interconnect also includes a second mating structure having a second electrode mounted to the second media. The first mating structure is connectable with the second mating structure to connect the interconnect so that, when connected, the first electrode, the thin film dielectric, and the second electrode form a thin film capacitor between the first media and the second media and connect the first signal channel and the second signal channel to form a connected signal channel.

### CROSS-REFERENCE TO RELATED APPLICATIONS

This application claims the benefit of co-pending U.S. provisional patent application Ser. No. 63/568,309 filed Mar. 21, 2024. The aforementioned related patent application is herein incorporated by reference in its entirety.

### TECHNICAL FIELD

Embodiments presented in this disclosure generally relate to electrical interconnects, such as electrical interconnects used in networking applications, pluggable optics, and artificial intelligence hardware, among others.

### BACKGROUND

A high-speed channel's performance is often impacted by discontinuities that, no matter how well controlled, result in impedance changes, reflections, and potential sources of crosstalk. These discontinuities result from die bonds, substrate vias, substrate sockets or bonds, printed circuit board (PCB) vias, blocking caps, transitions to/from connector lead frames, etc.

High-speed channels across PCB are becoming challenging due to bandwidth limitations. Cabled options offer some potential advantages but also come with their own list of implementation challenges. With higher density equipment, physical interconnects become increasingly challenging as both speeds and densities increase.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIGS. 1A and 1B depict schematic views of an apparatus having an interconnect according to one or more aspects of the present disclosure, with the interconnect being shown in an unconnected configuration in FIG. 1A and a connected configuration in FIG. 1B.

FIGS. 2A and 2B depict schematic views of an apparatus having an interconnect according to one or more aspects of the present disclosure, with the interconnect being shown in an unconnected configuration in FIG. 2A and a connected configuration in FIG. 2B.

FIGS. 3A and 3B depict schematic views of an apparatus having a plurality of interconnects and a plurality of conductive blocks according to one or more aspects of the present disclosure, with the interconnects and conductive blocks being shown in an unconnected configuration in FIG. 3A and a connected configuration in FIG. 3B.

FIGS. 3C and 3D depict schematic views of an apparatus having a plurality of interconnects and a plurality of conductive blocks according to one or more aspects of the present disclosure, with the interconnects and conductive blocks being shown in an unconnected configuration in FIG. 3C and a connected configuration in FIG. 3D.

FIG. 4 depicts a schematic cross-sectional view of an apparatus having a plurality of interconnects and a plurality of conductive blocks according to one or more aspects of the present disclosure.

FIGS. 5A and 5B depict schematic views of an apparatus having a plurality of interconnects and a plurality of conductive blocks according to one or more aspects of the present disclosure.

FIG. 6 depicts a schematic cross-sectional view of an apparatus having a plurality of interconnects and a plurality of conductive blocks according to one or more aspects of the present disclosure.

FIG. 7 depicts a schematic cross-sectional view of an apparatus having a plurality of interconnects and a plurality of conductive blocks according to one or more aspects of the present disclosure.

FIG. 8 depicts a schematic view of an apparatus having a plurality of interconnects and a plurality of conductive blocks according to one or more aspects of the present disclosure.

FIGS. 9A, 9B, and 9C depicts schematic view of various apparatuses each having interconnects and conductive blocks according to one or more aspects of the present disclosure.

FIGS. 10A and 10B depict schematic views of an assembly having an interconnect according to one or more aspects of the present disclosure.

FIG. 11 provides a flow diagram for a method of connecting an apparatus having at least one interconnect according to one or more aspects of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

In one aspect, an apparatus is provided. The apparatus includes a first media providing a first signal channel, a second media providing a second signal channel, and an interconnect. The interconnect includes a first mating structure that includes a first electrode mounted to the first media and a thin film dielectric disposed on the first electrode. Further, the interconnect includes a second mating structure having a second electrode mounted to the second media. The first mating structure is connectable with the second mating structure to connect the interconnect so that, when connected, the first electrode, the thin film dielectric, and the second electrode form a thin film capacitor between the first media and the second media and connect the first signal channel and the second signal channel to form a connected signal channel, e.g., a high-speed and/or AC-coupled signal channel.

In another aspect, an apparatus is provided. The apparatus includes an input dielectric layer having a power input pad and a ground input pad; an output dielectric layer having a power output pad and a ground output pad; a power layer that provides a first electrode; a ground layer that provides a second electrode; a dielectric layer having a first portion and a second portion, wherein the first portion has a higher dielectric constant than the second portion; a power channel having the power layer, the input and output power pads, a first power via, and a second power via, the first power via electrically couples the power input pad with the power layer, and the second power via electrically couples the power layer with the power output pad and also extends through, and is electrically isolated from, the ground layer; and a ground channel having the ground layer, the input and output ground pads, a first ground via, and a second ground via, the first ground via electrically couples the ground input pad with the ground layer, and the second ground via electrically couples the ground layer with the ground output pad. The input and output dielectric layers, the dielectric layer, the power layer, and the ground layer are stacked to form an interconnect and so that the dielectric layer is arranged between, and contacts, the first and second electrodes so as to form a decoupling capacitor to decouple the power and ground channels.

In yet another aspect, an apparatus is provided. The apparatus includes a first media providing a first signal channel, a second media providing a second signal channel, a conductive block mounted to the first media, the second media, or having conductive block structures mounted to both the first media and the second media. The apparatus also includes an interconnect that includes a first mating structure that includes a first electrode pad mounted to the first media and a thin film dielectric disposed on the first electrode pad; and a second mating structure having a second electrode pad mounted to the second media. The first mating structure is removably connectable with the second mating structure to connect the interconnect so that, when connected, the first electrode pad, the thin film dielectric, and the second electrode pad form a thin film capacitor between the first media and the second media to provide a DC blocking function and to connect the first signal channel and the second signal channel to form a connected signal channel. In addition, when the conductive block contacts the first media and the second media, the conductive block provides a conductive pathway between the first media and the second media.

In a further aspect, a method is provided. The method includes providing a first mating structure of an interconnect, the first mating structure being coupled with a first media that provides a first signal channel, the first mating structure having a first electrode and a thin film dielectric, the first electrode being mounted to the first media and the thin film dielectric being disposed on the first electrode. The method also includes providing a second mating structure of the interconnect, the second mating structure being coupled with a second media that provides a second signal channel, the second mating structure having a second electrode mounted to the second media. Further, the method includes connecting the first mating structure with the second mating structure so that, when the interconnect is connected, the first electrode, the thin film dielectric, and the second electrode form a thin film capacitor between the first media and the second media and connect the first signal channel and the second signal channel to form a connected signal channel.

### Example Embodiments

Embodiments disclosed herein relate to electrical interconnects that can enable high-density mateable interfaces with high-speed performance, without requiring excessive forces to maintain or enable this performance. Such electrical interconnects can be used in electrical and electro-optical apparatuses, for example. For instance, the disclosed interconnects can be applicable to a number of interconnect applications, including: application-specific integrated circuit (ASIC) package sockets; printed circuit board (PCB) to PCB; ASIC substrate to PCB; interposer to PCB/interposer; and pluggable module interfaces.

In one or more aspects, an apparatus can include one or more interconnects that are each formed by bringing mating structures embedded or attached to separate media into contact with one another. When the mating structures are brought into contact with one another, planar thin-film (TF) capacitors can be formed and a connection for a high-speed signal can be provided, as well as a DC blocking function. In one or more examples, the mating structures can be formed by planar pads mounted to separate media. For instance, in one or more examples, an assembly can include a first media (e.g., PCB) and a second media (e.g., a substrate). A plurality of first mating structures can be coupled with the first media and a plurality of second mating structures can be coupled with the second media. The first mating structures can each include a first electrode and a thin film dielectric disposed on the first electrode, and the second mating structures can each include a second electrode. The first media can be arranged relative to the second media so that the first and second mating structures are aligned, and the first media can be moved so that the first mating structures contact respective ones of the second mating structures. The thin film dielectrics can be sandwiched between the electrodes to form the TF capacitors. As noted above, the TF capacitors can provide high-speed channels and can block unwanted DC voltage from passing thereby, which can allow for fewer impedance transitions due to the DC block being intrinsic to the interface. In addition, the interconnects can be pseudo contactless, or rather, require very little or negligible compressive force to become connected. Also, the disclosed interconnect architecture lends itself to enabling high density fields of mateable (and re-mateable) contacts.

Accordingly, the interconnects disclosed herein can provide a contacting mechanism that offers a high-density pad field with enhanced signal integrity (SI) performance, manufacturability, and operational feasibility. Further, the disclosed interconnects can allow for simultaneously minimizing and/or eliminating the source of conventional channel transitions while opening up the potential for wider interfaces that mitigate many of the challenges that wider interfaces bring. Moreover, the disclosed interconnects can be used in conjunction with conductive blocks that, when connected, provide non-capacitive or fully conductive pathways between separate media. In addition, in one or more examples, the disclosed interconnects can be specifically arranged for power and/or ground transmission.

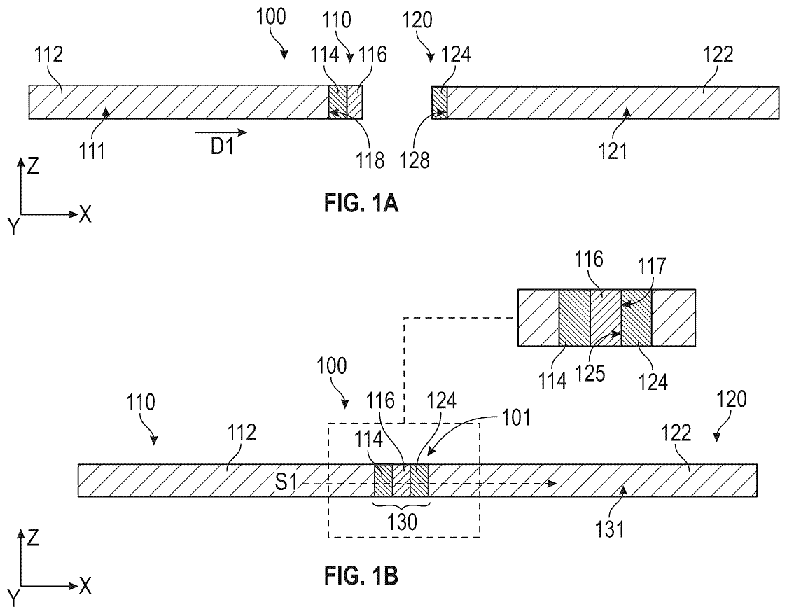

Turning now to the drawings, FIGS. 1A and 1B depict an apparatus 100 having an interconnect 101 according to one or more aspects of the present disclosure. In FIG. 1A, the interconnect 101 is in an unconnected configuration, or open configuration, while the interconnect 101 is in a connected configuration in FIG. 1B, or closed configuration. The interconnect 101 can be an electrical interconnect, for example, and can be implemented in any number of applications, such as networking applications, pluggable optics, and artificial intelligence hardware, among others. For reference, an X-direction, a Y-direction, and a Z-direction are defined and are mutually perpendicular to one another.

As depicted in FIGS. 1A and 1B, the apparatus 100 includes a first media 112, a second media 122, and the interconnect 101, which is formed by a first mating structure 110 that is coupled with the first media 112 and a second mating structure 120 that is coupled with the second media 122. The first mating structure 110, which forms a first part of the interconnect 101, includes a first electrode 114 mounted to the first media 112. The first electrode 114, which is arranged as a pad, can be attached to an end face 118 of the first media 112. The first mating structure 110 also includes a thin film dielectric 116 mounted to the first electrode 114. The thin film dielectric 116 can be formed on the first electrode 114 by way of a deposition process, for example. The thin film dielectric 116 can function as the contact interface, as will be explained further below. The first media 112 provides a first signal channel 111 along which signals can travel. The second mating structure 120, which forms a second part of the interconnect 101, includes a second electrode 124 mounted to the second media 122. The second electrode 124, which is arranged as a pad, can be attached to an end face 128 of the second media 122. The second media 122 provides a second signal channel 121 along which signals can travel.

The first mating structure 110 is connectable with the second mating structure 120. For instance, the first mating structure 110 can be moved in a direction D1 toward the second mating structure 120 as shown in FIG. 1A. When the first mating structure 110 engages the second mating structure 120, the interconnect 101 is arranged in a connected configuration, e.g., as depicted in FIG. 1B. The first mating structure 110 is connectable with the second mating structure 120 to connect the interconnect 101 so that, when connected, the first electrode 114, the thin film dielectric 116, and the second electrode 124 form a thin film capacitor 130 between the first media 112 and the second media 122 and connect the first signal channel 111 and the second signal channel 121 to form a connected channel 131 (e.g., a high-speed electrical signal channel). Accordingly, when the first mating structure 110 is connected with the second mating structure 120 signals S1 can travel along the connected channel 131 as shown in FIG. 1B. The thin film capacitor 130 can provide a DC blocking function. For instance, the thin film capacitor 130 can block unwanted DC voltage, acting as an open to the DC voltage along the signal path with the thin film dielectric 116 not allowing the unwanted DC voltage to pass therethrough.

In one or more examples, when the first mating structure 110 is connected with the second mating structure 120, the thin film dielectric 116 contacts the second electrode 124, e.g., as shown in FIG. 1B. In at least some examples, as illustrated in the close-up in FIG. 1B, the thin film dielectric 116 has a contact face 117 that is planar and the second electrode 124 has a contact face 125 that is planar. Accordingly, when the first mating structure 110 is connected with the second mating structure 120, the contact face 117 of the thin film dielectric 116 mates with the contact face 125 of the second electrode 124 in a planar face-to-planar face manner.

Moreover, in one or more examples, the first mating structure 110 can be removably connectable with the second mating structure 120. In this regard, after the first and second mating structures 110, 120 are connected, the first and second mating structures 110, 120 can be disconnected from one another, and then reconnected as desired. Stated differently, in one or more examples, the first and second mating structures 110, 120 are not permanently affixed to one another and can be disconnected and/or reconnected as desired.

Advantageously, the architecture of the interconnect 101 can simultaneously address minimizing and/or eliminating the source of channel transitions while opening up the potential for wider interfaces that mitigate many of the challenges that wider interfaces bring. Further, the blocking capacitor can be embedded into the end face of a channel media, which then becomes the contact interface to the connecting media. This can be done without excessive compression force, or rather being pseudo contactless, and also embeds the DC blocking function, which reduces or eliminates the need to implement discrete capacitors elsewhere. This can save area and reduce transitions in the channel.

In accordance with one or more other examples of the present disclosure, an interconnect can be formed using an “electrode-to-electrode mating” approach in which a first mating structure has a pair of electrodes sandwiching a thin film dielectric. In such examples, when the first and second mating structures are connected, a contact face of one of the electrodes of the first mating structure can contact the electrode of the second mating structure, providing an electrode-to-electrode interface (e.g., a metal-to-metal interface). An interconnect with such architecture can achieve contact surface robustness and design consistency, among other benefits. An example is provided below.

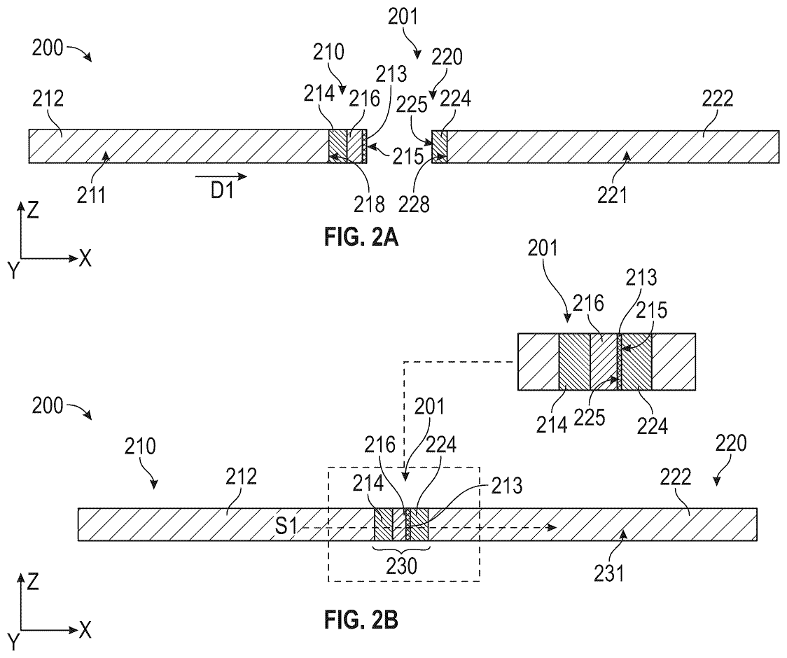

FIGS. 2A and 2B depict an apparatus 200 having an interconnect 201 according to one or more aspects of the present disclosure. In FIG. 2A, the interconnect 201 is in an open or unconnected configuration, while the interconnect 201 is in a closed or connected configuration in FIG. 2B. The interconnect 201 can be an electrical interconnect, for example, and can be implemented in any number of applications.

The apparatus 200 of FIGS. 2A and 2B is arranged in a similar manner as the apparatus 100 of FIGS. 1A and 1B, except as otherwise provided. The apparatus 200 includes a first media 212, a second media 222, and the interconnect 201, which is formed by a first mating structure 210 that is coupled with the first media 212 and a second mating structure 220 that is coupled with the second media 222. The first mating structure 210, which forms a first part of the interconnect 201, includes a first electrode 214 mounted to an end face 218 of the first media 212. The first mating structure 210 also includes a thin film dielectric 216 mounted to the first electrode 214 and a thin conductive layer 213 mounted to the thin film dielectric 216 opposite the first electrode 214. In this way, the first electrode 214 and the thin conductive layer 213 can sandwich the thin film dielectric 216 therebetween. The thin conductive layer 213 can be formed of a metal, such as copper. The first media 212 provides a first signal channel 211 along which signals can travel. The second mating structure 220, which forms a second part of the interconnect 201, includes a second electrode 224 mounted to an end face 228 of the second media 222. The second media 222 provides a second signal channel 221 along which signals can travel.

The first mating structure 210 is connectable with the second mating structure 220. For instance, the first mating structure 210 can be moved in a direction D1 toward the second mating structure 220 as shown in FIG. 2A. When the first mating structure 210 engages the second mating structure 220, the interconnect 201 is arranged in a connected configuration, e.g., as depicted in FIG. 2B. Moreover, when the first mating structure 210 is connected with the second mating structure 220, the thin conductive layer 213 can contact the second electrode 224. In at least some examples, as illustrated in the close-up in FIG. 2B, the thin conductive layer 213 has a contact face 215 that is planar. Accordingly, when the first mating structure 210 is connected with the second mating structure 220, the contact face 215 of the thin conductive layer 213 mates with a contact face 225 of the second electrode 224 in a planar face-to-planar face manner.

The first mating structure 210 is connectable with the second mating structure 220 so that, when the interconnect 201 is connected, the first electrode 214, the thin film dielectric 216, and the second electrode 224 form a thin film capacitor 230 between the first media 212 and the second media 222 and connect the first signal channel 211 and the second signal channel 221 to form a connected channel 231. Accordingly, when the first mating structure 210 is connected with the second mating structure 220 signals S1 can travel along the connected channel 231 as shown in FIG. 2B. The thin film capacitor 230 can provide a DC blocking function, e.g., to block unwanted DC voltage. Moreover, the electrode-to-electrode interface, e.g., between the thin conductive layer 213 and the second electrode 224 can provide enhanced contact surface robustness and design consistency of the interconnect 201, among other benefits.

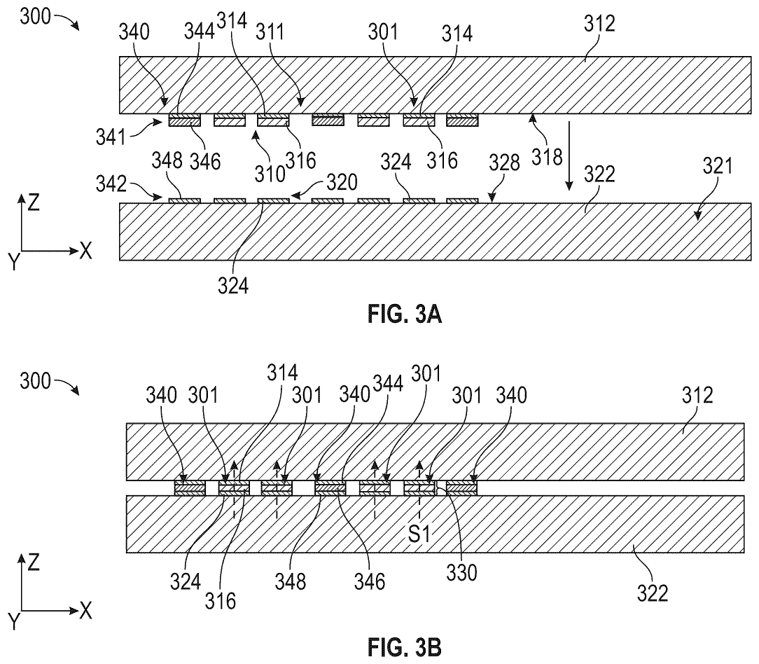

FIGS. 3A and 3B depict an apparatus 300 having a plurality of interconnects 301 and a plurality of conductive blocks 340 according to one or more aspects of the present disclosure. In FIG. 3A, neither the interconnects 301 nor the conductive blocks 340 are connected, and thus they are in an open or unconnected configuration. In FIG. 3B, the interconnects 301 and the conductive blocks 340 are connected, and thus they are in a closed or connected configuration.

As illustrated in FIGS. 3A and 3B, the apparatus 300 includes a first media 312 (e.g. a first PCB), a second media 322 (e.g., a second PCB), and the interconnects 301, which are formed by respective first and second mating structures 310, 320 coupled with the first media 312 and the second media 322, respectively. Each one of the first mating structures 310 has a first electrode 314 and a thin film dielectric 316 mounted to the first electrode 314, with the first electrode 314 being mounted to an end face 318 of the first media 312. The first media 312 provides a first signal channel 311 along which signals can travel. Each one of the second mating structures 320 has a second electrode 324 mounted to an end face 328 of the second media 322. The second media 322 provides a second signal channel 321 along which signals can travel.

The first mating structures 310 are connectable with respective ones of the second mating structures 320 so that, when connected, the first electrode 314, the thin film dielectric 316, and the second electrode 324 of a given one of the interconnects 301 form a thin film capacitor 330 between the first media 312 and the second media 322 and connect the first signal channel 311 and the second signal channel 321 to form a connected channel 331. In this regard, when the first mating structures 310 are connected with their respective second mating structures 320, signals S1 can travel along the connected channel 331 as shown in FIG. 3B. In one or more examples, one or more of the signals S1 can travel in the opposite direction than the direction shown in FIG. 3B.

As further shown in FIGS. 3A and 3B, the apparatus 300 includes the conductive blocks 340, which are formed by respective first and second block structures 341, 342 coupled with the first media 312 and the second media 322, respectively. Each one of the first block structures 341 has a first block electrode 344 and a conductive elastomer 346 mounted to the first block electrode 344, with the first block electrode 344 being mounted to the end face 318 of the first media 312. Each one of the second block structures 342 has a second block electrode 348 mounted to the end face 328 of the second media 322. In one or more examples, one or more of the conductive elastomers 346 can be mounted to their corresponding second block electrodes 348 rather than to their respective first block electrodes 344. In this regard, each one of the conductive blocks 340 has the first block electrode 344, the second block electrode 348, and the conductive elastomer 346 mounted to the first block electrode 344 or the second block electrode 348.

When the conductive blocks 340 are in a connected configuration, e.g., as shown in FIG. 3B, the conductive elastomers 346 are arranged between, and in contact with, their respective first and second block electrodes 344, 348. Consequently, the conductive blocks 340 form respective conductive pathways between the first media 312 and the second media 322. In one or more examples, the conductive pathways can be non-capacitive or fully conductive. The first and second block electrodes 344, 348 can be plated pads, for example.

In one or more examples, when the first block structures 341 are connected with their corresponding second block structures 342, the conductive elastomers 346 can contact respective ones of the second block electrodes 348, e.g., as shown in FIG. 3B. In at least some examples, the conductive elastomers 346 can each have a contact face that is planar and the second block electrodes 348 can each have a contact face that is planar. Accordingly, when the first block structures 341 are connected with their respective second block structures 342, the contact faces of the conductive elastomers 346 can mate with the contact faces of respective ones of the second block electrodes 348 in a planar face-to-planar face manner. Indeed, the architecture of the interconnects 301 and the conductive blocks 340 can enable the simultaneous formation of connected channels and conductive pathways with negligible compressive force.

In one or more other examples, with reference to FIGS. 3C and 3D, the conductive blocks 340 of the apparatus 300 can additionally include, or alternatively be, plated pillars 350 mounted to the first media 312 and/or the second media 322. The plated pillars 350 can each have a thickness substantially the same as the interconnects 301. While the conductive blocks 340 are mounted to the end face 318 of the first media 312 in FIGS. 3C and 3D, in alternative examples, one or more of the conductive blocks 340 can be mounted to the end face 328 of the second media 322. When the interconnects 301 are connected, the conductive blocks 340 arranged as plated pillars can each provide conductive pathways between the first media 312 and the second media 322. The plated pillars can be plated with electrically conductive material, such as copper.

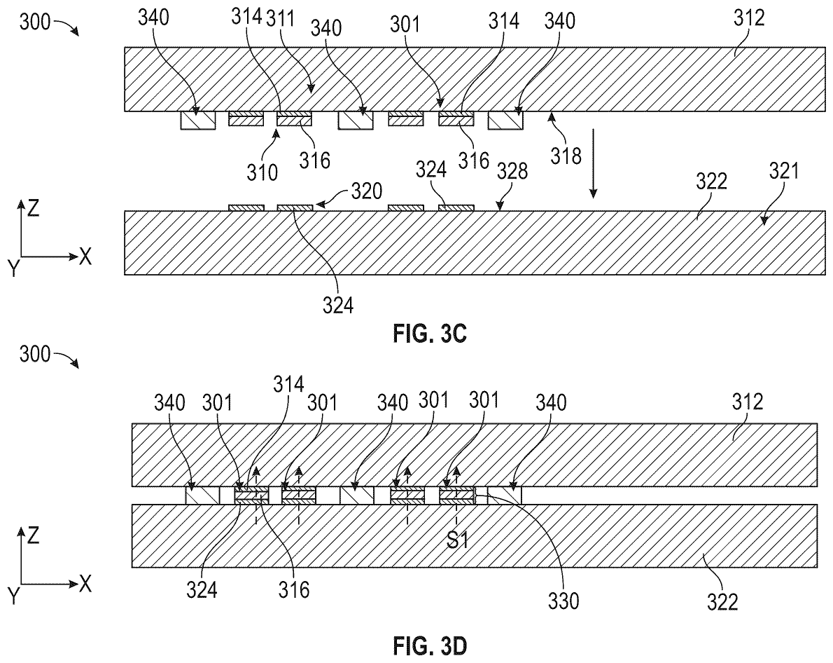

FIG. 4 depicts an apparatus 400 having a plurality of interconnects 401 and a plurality of conductive blocks 440 according to one or more aspects of the present disclosure. The apparatus 400 can be a chip apparatus, for example. The interconnects 401 and conductive blocks 440 can be constructed in a similar manner as described above with respect to FIGS. 3A, 3B, 3C, 3D.

As shown in FIG. 4, the apparatus 400 includes a PCB 403, a substrate 405, a die 407, and socket walls can flank the substrate 405. The die 407 can be an ASIC, or chip substrate, for example. The substrate 405 can be mounted on the PCB 403 with a first set of the interconnects 401 and a first set of the conductive blocks 440 being arranged therebetween. The interconnects 401 of the first set can provide connected channels (e.g., high speed channels) between the PCB 403 and the substrate 405. The conductive blocks 440 can provide conductive pathways (e.g., non-capacitive, electrical ground pathways) between the PCB 403 and the substrate 405. The interconnects 401 of the first set can each have their first and second mating structures respectively fabricated on, or embedded within, the substrate 405 and the PCB 403. When the first and second mating structures of the interconnects 401 of the first set are connected as shown in FIG. 4, thin film capacitors 430 are formed that each provide both a high speed connected signal channel and a DC blocking function. Moreover, discrete capacitors between the PCB 403 and the substrate 405 can be eliminated or reduced. The conductive blocks 440 of the first set, which are non-capacitive or fully conductive, provide conductive pathways between the PCB 403 and the substrate 405, e.g., for electrical ground pathways.

In addition, like the PCB-to-substrate interface, the die-to-substrate interface can include interconnects and conductive blocks. As depicted in FIG. 4, the die 407 can be mounted on the substrate 405 with a plurality of conductive bumps 409 (e.g., solder bumps), and a second set of the interconnects 401 and a second set of the conductive blocks 440 can be embedded within the substrate 405 as depicted in FIG. 4. The top electrodes of the interconnects 401 and the top block electrodes of the conductive blocks 440 can be electrically coupled with one or more of the conductive bumps 409. The interconnects 401 of the second can provide connected channels (e.g., high speed channels) between the substrate 405 and the die 407. The interconnects 401 embedded within the substrate 405 can form thin film capacitors 430 that each provide both a high speed connected signal channel and a DC blocking function. In this regard, discrete capacitors between the substrate 405 and the die 407 can be eliminated or reduced. The conductive blocks 440 of the second set, which are non-capacitive or fully conductive, provide conductive pathways between the substrate 405 and the die 407, e.g., for electrical ground pathways.

Accordingly, the low contact force embedded thin film capacitors 430 can be fabricated on or into the PCB 403, the substrate 405, and/or the die 407. Thus, the interconnects 401 can be used in the substrate-to-PCB and die-to-substrate interfaces in an ASIC package. The interconnects 401 can offer packaging efficiency, including the reduction of discrete capacitors, and can simplify manufacturing. Moreover, improved channel performance due to reduced discontinuities can be achieved with the interconnects 401. Further, a socket approach, potentially useful for manufacturability without the challenges associated with an LGA socket (e.g. compressive force), can be accomplished.

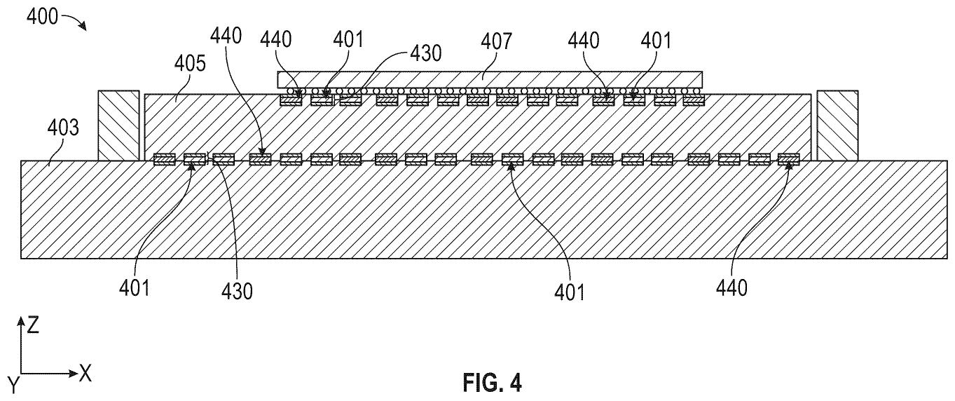

FIGS. 5A and 5B depict an apparatus 500 having a plurality of interconnects 501 and a plurality of conductive blocks 540 according to one or more aspects of the present disclosure. FIG. 5A is a schematic cross-sectional view of the apparatus 500 and FIG. 5B is a schematic top view of the apparatus 500. The apparatus 500 can be an electro-optical apparatus, such as for co-packaged optics (CPO), co-packaged copper (CPC), and/or near packaged optics or copper (NPO/NPC) applications. The interconnects 501 and conductive blocks 540 can be constructed in a similar manner as described above with respect to FIGS. 3A, 3B, 3C, 3D.

As shown in FIGS. 5A and 5B, the apparatus 500 includes a main substrate 560 and a main integrated circuit (IC), or main IC 562. The main IC 562 is centrally located on the main substrate 560, and can be a networking ASIC, such as a network processing unit (NPU), for example. The apparatus 500 also includes a plurality of optical engines 564 arranged about the main IC 562. There are eight (8) optical engines 564 shown in FIG. 5B (only one in FIG. 5A). The main IC 562 can be electrically coupled with each one of the optical engines 564, e.g., by way of electrical traces.

Each one of the optical engines 564 includes a module substrate 566, a photonic die 568, an electrical integrated circuit, or EIC 570, and a fiber array unit (FAU), or FAU 572, coupling one or more optical fibers 574 with the photonic integrated circuit (PIC) of the photonic die 568. In FIG. 5A, the FAU 572 surface couples the optical fibers 574 with the PIC of the photonic die 568. Optical signals can travel along the optical fibers 574 and coupled into the photonic die 568, e.g., by way of grating couplers. The optical signals can travel along optical waveguides of the PIC and can be converted into electrical signals by one or more optical-to-electrical converters (e.g., one or more photodetectors or photodiodes) within the PIC of the photonic die 568. The electrical signals can be routed to the EIC 570 for processing. Electrical signals from the EIC 570 can travel within the PIC of the photonic die 568 and can be converted into optical signals by one or more electrical-to-optical converters (e.g., one or more modulators) within the PIC of the photonic die 568. The optical signals can be routed to the optical fibers 574 by way of the optical waveguides.

Further, the EIC 570 can be electrically coupled with the main IC 562 and can send and/or receive electrical signals therefrom. For instance, high-speed electrical signals from the EIC 570 can travel from the EIC 570 through the module substrate 566 via high-speed channels formed at least in part by a first set of the interconnects 501 embedded at or proximate a top surface of the module substrate 566. The first set of the interconnects 501 can each form thin film capacitors 530, each providing a high-speed channel and a DC blocking function. The high-speed electrical signals can travel through the module substrate 566 and into the main substrate 560 via a second set of the interconnects 501 arranged between the module substrate 566 and the main substrate 560. The second set of the interconnects 501 can each form thin film capacitors 530, each providing a high-speed channel and a DC blocking function. The high-speed electrical signals can then be directed to the main IC 562, e.g., by way of electrical traces as noted above.

In addition, a first set of conductive blocks 540 can provide respective conductive pathways (e.g., non-capacitive or fully conductive electrical pathways) between the photonic die 568 and the module substrate 566, e.g., for electrical ground pathways. A second set of conductive blocks 540 can provide respective conductive pathways (e.g., non-capacitive or fully conductive electrical pathways) between the module substrate 566 and the main substrate 560, e.g., for electrical ground pathways.

Accordingly, the low contact force thin film capacitors 530 can be fabricated on or into the main substrate 560, the module substrates 566, and/or the photonic die 568. Thus, the interconnects 501 can be used in the substrate-to-substrate and die-to-module substrate interfaces in CPO, NPO, and/or other packages. The interconnects 501 can offer packaging efficiency, including the reduction of discrete capacitors, and can simplify manufacturing. Moreover, improved channel performance due to reduced discontinuities can be achieved with the interconnects 501.

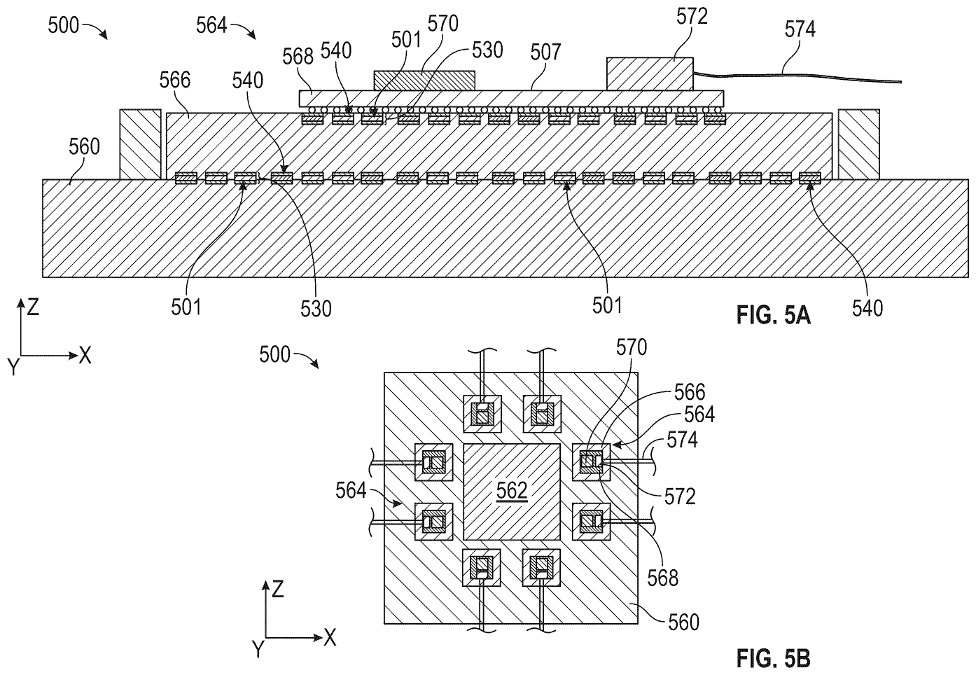

FIG. 6 depicts a schematic cross-sectional view of an apparatus 600 having a plurality of interconnects 601 and a plurality of conductive blocks 640 according to one or more aspects of the present disclosure. The apparatus 600 can be an electro-optical apparatus, for example. The interconnects 601 and conductive blocks 640 can be constructed in a similar manner as described above with respect to FIGS. 3A, 3B, 3C, 3D.

As shown in FIG. 6, the apparatus 600 includes a PCB 603, a substrate 605, and a die 607. The die 607 can be a photonic die, for example. The substrate 605 can be mounted on the PCB 603, e.g., by flip-chip bonding. The die 607 can be mounted on the substrate 605, e.g., by flip-chip bonding. The apparatus 600 also includes a connector 680 that can be electrically coupled with the PCB 603 when connected thereto. The connector 680 has a housing 682, a connector PCB 684 attached to the housing 682, and a plurality of multi-conductor cables 686 (e.g., twinaxial or “twinax” cables).

The interconnects 601 each include first and second mating structures 610, 620. In depicted example of FIG. 6, the first mating structures 610 of the interconnects 601 are embedded in the connector PCB 684, with each one of the first mating structures 610 having a first electrode 614 and a thin film dielectric 616. The second mating structures 620 are embedded within the PCB 603, with each one of the second mating structures 620 having a second electrode 624. The thin film dielectrics 616 and the second electrode 624 can each have planar contact faces to facilitate low contact force mating of the surfaces. In one or more other examples, a thin conductive layer can be mounted to the thin film dielectric 616 opposite the first electrode 614. In this way, the first electrode 614 and the thin conductive layer can sandwich the thin film dielectric 616 therebetween. The thin conductive layer can be formed of a metal, such as copper, and can have a planar contact face.

When the first and second mating structures 610, 620 are connected as shown in FIG. 6, thin film capacitors 630 are formed that each provide both a high speed connected signal channel and a DC blocking function. Accordingly, high-speed electrical signals can be routed between the connector 680 and the PCB 603 by way of the interconnects 601. Moreover, discrete capacitors between the PCB 603 and the connector 680 can be eliminated or reduced. Advantageously, the interconnects 601 can provide high density contacts with improved SI performance, allowing high speed electrical coupling between the multi-conductor cables 686 and the PCB 603. Further, the conductive blocks 640, which are non-capacitive or fully conductive, provide conductive pathways between the PCB 603 and the connector 680, e.g., for electrical ground pathways. The architecture of the interconnects 601 and the conductive blocks 640 can also enable low contact force mating of the connector 680 with the PCB 603 (e.g., pseudo contactless). The connector 680 can also be removably connectable or re-mateable with the PCB 603.

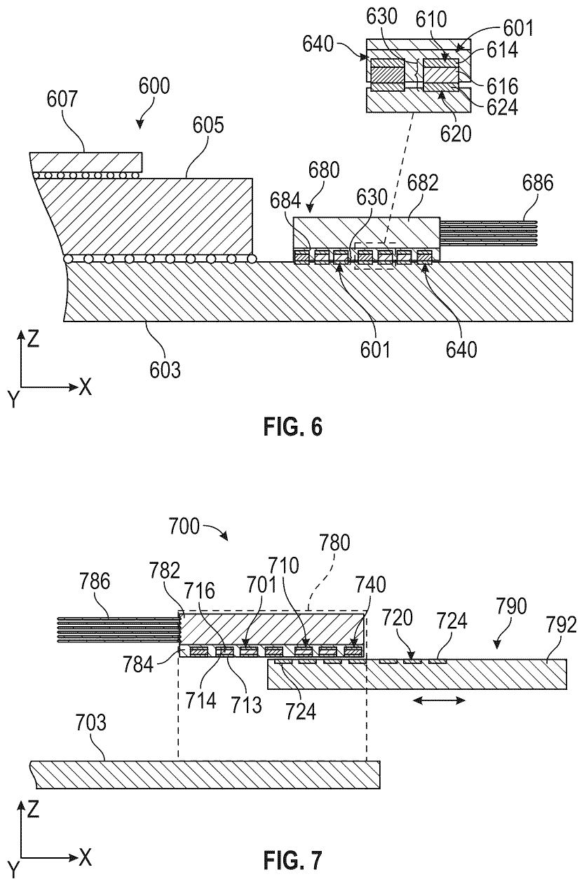

FIG. 7 depicts a schematic cross-sectional view of an apparatus 700 having a plurality of interconnects 701 and a plurality of conductive blocks 740 according to one or more aspects of the present disclosure. The apparatus 700 can be a connector apparatus connecting to an electro-optical apparatus, for example. The interconnects 701 and conductive blocks 740 can be constructed in a similar manner as described above with respect to FIGS. 3A, 3B, 3C, 3D.

As shown in FIG. 7, the apparatus 700 includes a host PCB 703, a host connector 780 mounted on the host PCB 703, and a pluggable module 790. The host connector 780 has a housing 782, a connector PCB 784 attached to the housing 782, and a plurality of multi-conductor cables 786 (e.g., twinax cables) that are held by the housing 782. The pluggable module 790 is pluggable with, or insertable into, the host connector 780. For instance, the pluggable module 790 can be slide or moved along the X-direction in FIG. 7 to plug into the host connector 780. When received within the host connector 780, the pluggable module 790 can be electrically coupled with the host connector 780 by way of the interconnects 701 and the conductive blocks 740. The pluggable module 790 has a module PCB 792, among other components.

The interconnects 701 each include first and second mating structures 710, 720. In depicted example of FIG. 7, the first mating structures 710 of the interconnects 701 are embedded in the connector PCB 784, with each one of the first mating structures 710 having a first electrode 714, a thin film dielectric 716, and a thin conductive layer 713 mounted to the thin film dielectric 716 opposite the first electrode 714. The second mating structures 620 are embedded within the module PCB 792, with each one of the second mating structures 620 having a second electrode 624. The thin conductive layers 713 and the second electrodes 724 can each have planar contact faces to facilitate low contact force mating of the surfaces. In one or more other examples, the thin conductive layer can be omitted. In this way, the thin film dielectric 716 can mate with the second electrodes 724, when aligned.

When the first and second mating structures 710, 720 are connected (the first and second mating structures 710, 720 are not connected in FIG. 7 as the pluggable module 790 is not fully inserted or received within the host connector 780) thin film capacitors are formed that each provide both a high speed connected signal channel and a DC blocking function. Accordingly, high-speed electrical signals can be routed between the pluggable module 790 and the host connector 780 by way of the interconnects 701. Advantageously, the interconnects 701 can provide high density contacts with improved SI performance, allowing high speed electrical coupling between the multi-conductor cables 786 and the pluggable module 790. Further, the conductive blocks 740, which are non-capacitive or fully conductive, provide conductive pathways between the pluggable module 790 and the host connector 780, e.g., for electrical ground pathways. The architecture of the interconnects 701 and the conductive blocks 740 can also enable low contact force mating of the pluggable module 790 and the host connector 780 (e.g., pseudo contactless). The pluggable module 790 can also be removably connectable or re-mateable with the host connector 780.

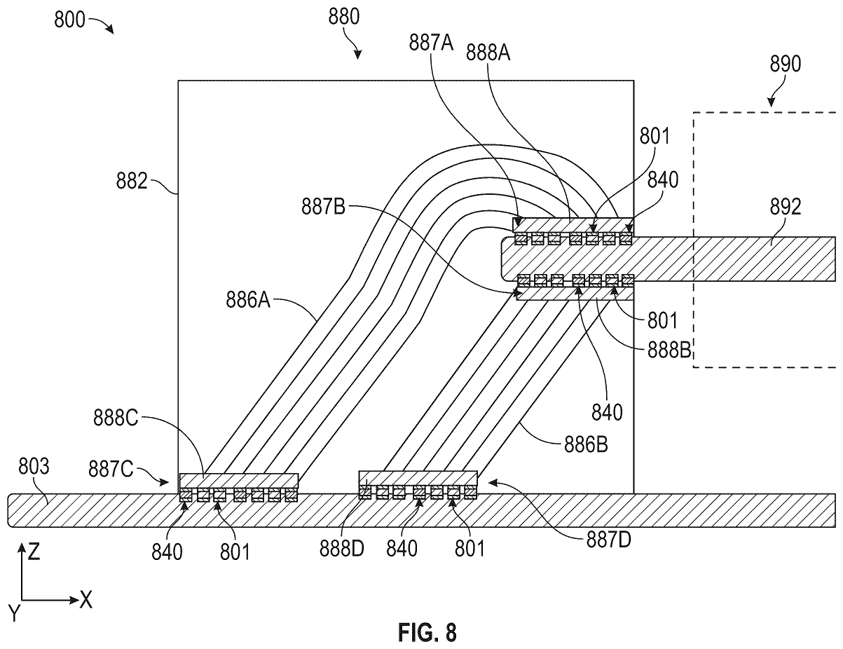

FIG. 8 depicts a schematic cross-sectional view of an apparatus 800 having a plurality of interconnects 801 and a plurality of conductive blocks 840 according to one or more aspects of the present disclosure. The apparatus 800 can be an electro-optical apparatus, for example. The interconnects 801 and conductive blocks 840 can be constructed in a similar manner as described above with respect to FIGS. 3A, 3B, 3C, 3D.

As shown in FIG. 8, the apparatus 800 includes a host PCB 803, a host connector 880 mounted on the host PCB 803, and a pluggable module 890. The host connector 880 has a housing 882 and a plurality of multi-conductor cables (e.g., twinax cables), including a first set of multi-conductor cables 886A and a second set of multi-conductor cables 886B, with the cables of both sets being held by the housing 882. The pluggable module 890 is pluggable with, or insertable into, the host connector 880. For instance, the pluggable module 890 can be slide or moved along the X-direction in FIG. 8 to plug into the host connector 880. When received within the host connector 880, the pluggable module 890 can be electrically coupled with the host connector 880 by way of the interconnects 801 and the conductive blocks 840. The pluggable module 890 has a module PCB 892, among other components.

The multi-conductor cables 886A of the first set have caps 887A, 887C at their ends and the multi-conductor cables 886B of the second set have caps 887B, 887D at their ends. Each one of the caps 887A, 887B, 887C, 887D has a cap PCB with first mating structures attached to, or embedded within, the cap PCB. For instance, the caps 887A, 887C have cap PCBs 888A, 888C, and the caps 887B, 887D have cap PCBs 888B, 888D. The first mating structures, with each one having a first electrode and a thin film dielectric mounted thereto, are attached to, or embedded within, the cap PCBs 888A, 888B, 888C, 888D.

Both the host PCB 803 and the module PCB 892 include the second mating structures. Each one of the second mating structures has a second electrode mounted to the host PCB 803 or the module PCB 892 (e.g., attached to an end face, or embedded therein). The host PCB 803 includes second mating structures arranged to mate with respective first mating structures of the caps 887C, 888D. The module PCB 892 includes second mating structures arranged to mate with respective first mating structures of the caps 887A, 888B. In this regard, the second mating structures are arranged along a top surface and a bottom surface of the module PCB 892.

When the first and second mating structures are connected, thin film capacitors are formed that each provide both a high speed connected signal channel and a DC blocking function. Accordingly, high-speed electrical signals can be routed between the pluggable module 890 and the multi-conductor cables 886A by way of the interconnects 801 at the cap 887A, as well as between the multi-conductor cables 886A and the host PCB 803 by way of the interconnects 801 at the cap 887C. Also, high-speed electrical signals can be routed between the pluggable module 890 and the multi-conductor cables 886B by way of the interconnects 801 at the cap 887B, as well as between the multi-conductor cables 886B and the host PCB 803 by way of the interconnects 801 at the cap 887D. Advantageously, the interconnects 801 can provide high density contacts with improved SI performance, allowing high speed electrical coupling between the multi-conductor cables 886A, 886B and the PCBs 803, 892. Further, the conductive blocks 840, which are non-capacitive or fully conductive, provide conductive pathways between the pluggable module 890 and the multi-conductor cables 886A, 886B, and between the multi-conductor cables 886A, 886B and the host PCB 803, e.g., for electrical ground pathways. The architecture of the interconnects 801 and the conductive blocks 840 can also enable low contact force mating of the pluggable module 890 and the host connector 880 (e.g., pseudo contactless). The pluggable module 890 can also be removably connectable or re-mateable with the host connector 880.

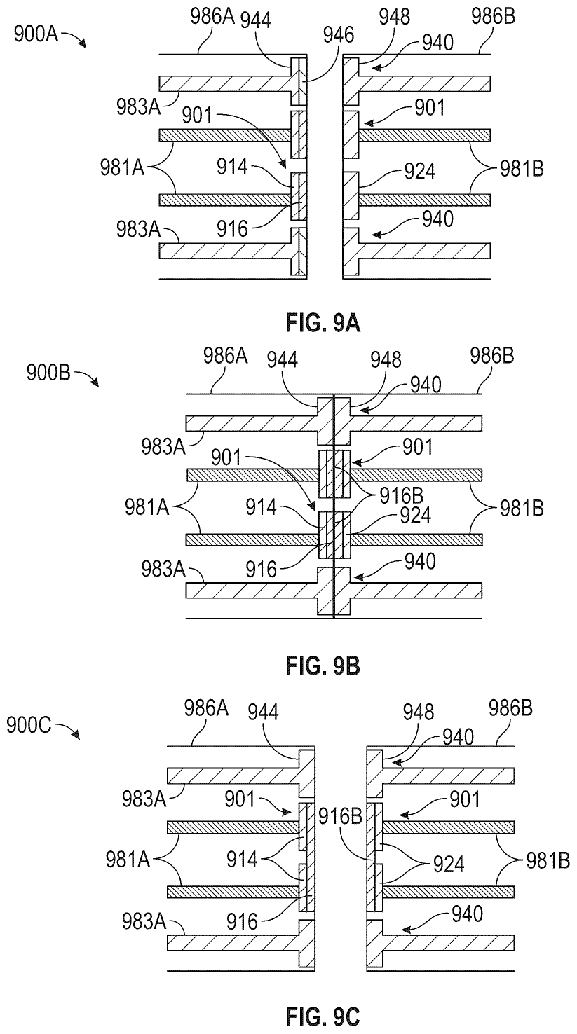

FIGS. 9A, 9B, 9C depicts schematic views of apparatuses 900A, 900B, 900C each having a plurality of interconnects 901 and a plurality of conductive blocks 940 according to one or more aspects of the present disclosure.

In FIG. 9A, the apparatus 900A includes a first multi-conductor cable 986A and a second multi-conductor cable 986B arranged to mate with one another. In FIG. 9A, the interconnects 901 and the conductive blocks 940 are in an unconnected configuration. The first multi-conductor cable 986A includes signal wires 981A and ground wires 983A flanking the signal wires 981A. The signal wires 981A each include first mating structures, with each first mating structure having a first electrode 914 and a thin film dielectric 916. The ground wires 983A each include first block electrodes 944 and conductive elastomers 946 mounted to their respective first block electrode 944. The second multi-conductor cable 986B includes signal wires 981B and ground wires 983B flanking the signal wires 981B. The signal wires 981B each include second mating structures, with each second mating structure having a second electrode 924. The ground wires 983B each include second block electrodes 948.

The first and second multi-conductor cables 986A, 986B can be connected by aligning the first and second mating structures and moving the contact faces into contact with one another. The thin film dielectrics 916 can contact respective ones of the second electrodes 924 and the conductive elastomers 946 can contact respective ones of the second block electrodes 948. When connected, the interconnects 901 form thin film capacitors that each provide both a high speed connected signal channel and a DC blocking function. Accordingly, high-speed electrical signals can be routed between the first and second multi-conductor cables 986A, 986B by way of the interconnects 901. Advantageously, the interconnects 901 can provide high density contacts with improved SI performance, allowing high speed electrical coupling between the first and second multi-conductor cables 986A, 986B. Further, the conductive blocks 940, which are non-capacitive or fully conductive, provide conductive pathways between the multi-conductor cables 986A, 986B, e.g., for electrical ground pathways. The architecture of the interconnects 901 and the conductive blocks 940 can also enable low contact force mating of the between the first and second multi-conductor cables 986A, 986B. The first and second multi-conductor cables 986A, 986B can also be removably connectable or re-mateable with one another.

The apparatus 900B of FIG. 9B is similarly configured as the apparatus 900A of FIG. 9A, except that the second multi-conductor cable 986B of the apparatus 900B has second thin film dielectrics 916B mounted to respective ones of the second electrodes 924. Accordingly, when the first and second multi-conductor cables 986A, 986B are connected or in a connected configuration, e.g., as shown in FIG. 9B, the thin film dielectrics 916 of the first multi-conductor cables 986B contact respective ones of the second thin film dielectrics 916B of the second multi-conductor cables 986B. Also, for the apparatus 900B, the conductive elastomers 946 have been omitted. Accordingly, with the example of FIG. 9B, the first and second multi-conductor cables 986A, 986B can have symmetric interconnect and conductive block interfaces, which may facilitate assembly of the apparatus 900B, among other benefits.

The apparatus 900C of FIG. 9C is similarly configured as the apparatus 900B of FIG. 9B, except that a single thin film dielectric 916 is mounted to the first electrodes 914, which are mounted to separate ones of the signal wires 981B. Likewise, a single second thin film dielectric 916B is mounted to the second electrodes 924, which are mounted to separate ones of the signal wires 981B. Accordingly, when the first and second multi-conductor cables 986A, 986B are connected or in a connected configuration, the single thin film dielectric 916 contacts the second thin film dielectric 916B.

In one or more examples, the apparatuses 900A, 900B, 900C, can be fabricated by polishing and plating the signal wires and the ground wires. The wires can be plated with rectangular pads, e.g., to form the electrodes and block electrodes. Next, a thin film dielectric can be deposited onto the pads of the signal wires, e.g., using masked-based or pattern-based dielectric thin film deposition. In addition, optionally, one or of the pads associated with the ground wires can receive a conductive elastomer. With the first mating structures and first block structures formed, the twinax cable can be mated with a corresponding twinax cable having corresponding second mating structures and second block structures.

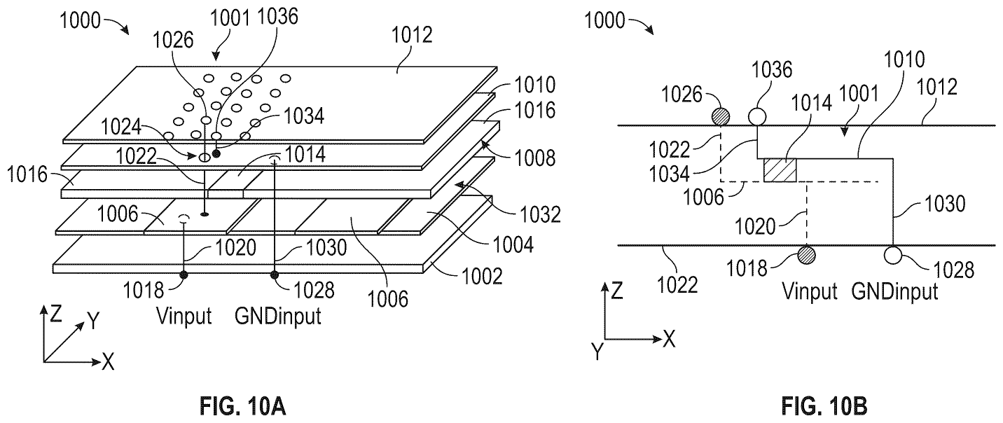

FIGS. 10A and 10B depict an apparatus 1000 having an interconnect 1001 arranged for electrical power transmission and noise decoupling. Using thin film capacitors that can be embedded within the PCB stack-up and in conjunction with placement of ground and power planes, an apparatus arranged in tightly integrated manner can achieve satisfactory noise decoupling. FIG. 10A shows an exploded perspective view of the apparatus 1000 while FIG. 10B shows a side electrical schematic of the apparatus 1000.

The apparatus 1000 can include a stack-up of layers, including a first dielectric layer 1002 (or input dielectric layer), a second dielectric layer 1004, one or more power layers 1006, a third dielectric layer 1008, a ground layer 1010, and a fourth dielectric layer 1012 (or output dielectric layer). The second dielectric layer 1004 is arranged on the first dielectric layer 1002. The one or more power layers 1006 (two power layers are depicted in FIG. 10A) are each arranged on the second dielectric layer 1004 and formed of an electrically conductive material (e.g., copper). The power layers can also be referred to as “power shapes”. The third dielectric layer 1008 is arranged on the one or more power layers 1006. A first portion 1014 of the third dielectric layer 1008 is formed of a dielectric material that has a higher dielectric constant, or DK value, than a second portion 1016 of the third dielectric layer 1008. At least one of the one or more power layers 1006 is arranged to contact the first portion 1014 of the third dielectric layer 1008. The ground layer 1010, which can be formed of an electrically conductive material (e.g., copper), is arranged on the third dielectric layer 1008. The fourth dielectric layer 1012 is arranged on the ground layer 1010.

A power input pad 1018 is attached to a bottom surface of the first dielectric layer 1002 and can provide a power input V_{INPUT}. A first power via 1020 is electrically coupled with the power input pad 1018 and traverses through both the first dielectric layer 1002 and the second dielectric layer 1004 and contacts one of the power layers 1006 (e.g., a bottom surface thereof). The first power via 1020 can be formed of electrically conductive material, such as copper. A second power via 1022 can contact the power layer 1006 (e.g., a top surface thereof), and can also be formed of electrically conductive material, such as copper. The second power via 1022 can traverse through the second portion 1016 of the third dielectric layer 1008, through a hole 1024 defined in the ground layer 1010 so that the second power via 1022 does not contact the ground layer 1010 (e.g., so that the second power via 1022 and the ground layer 1010 are electrically isolated from one another), and through the fourth dielectric layer 1012. The second power via 1022 can traverse through the fourth dielectric layer 1012 and contact a power output pad 1026 arranged on a top surface of the fourth dielectric layer 1012. Accordingly, electrical power can be transmitted through the stack-up by traveling from the power input pad 1018 to the first power via 1020, from the first power via 1020 to the power layer 1006, from the power layer 1006 to the second power via 1022, and from the second power via 1022 to the power output pad 1026.

A ground input pad 1028 is attached to the bottom surface of the first dielectric layer 1002 and provides a ground input GND_{INPUT}. A first ground via 1030 is electrically coupled with the ground input pad 1028 and traverses through the first dielectric layer 1002, the second dielectric layer 1004, a space 1032 or empty void defined between the second dielectric layer 1004 and the third dielectric layer 1008 (the space having a thickness along the Z-direction that corresponds with a thickness of the power layers 1006), and finally through the second portion 1016 of the third dielectric layer 1008. The first ground via 1030 traverses through the third dielectric layer 1008 and contacts the ground layer 1010 (e.g., a bottom surface thereof). The first ground via 1030 can be formed of electrically conductive material, such as copper. A second ground via 1034 can contact the ground layer 1010 (e.g., a top surface thereof), and can also be formed of electrically conductive material, such as copper. The second ground via 1034 can traverse through the fourth dielectric layer 1012 and can contact a ground output pad 1036 arranged on a top surface of the fourth dielectric layer 1012. Accordingly, electrical ground can be transmitted through the stack-up by traveling from the ground input pad 1028 to the first ground via 1030, from the first ground via 1030 to the ground layer 1010, from the ground layer 1010 to the second ground via 1034, and from the second ground via 1034 to the ground output pad 1036.

In one or more examples, the interconnect 1001 of the apparatus 1000 can include a first mating structure that includes a first electrode and a thin film dielectric disposed on the first electrode. For the apparatus 1000, the first electrode can be the power layer 1006 and the thin film dielectric can be the first portion 1014 of the third dielectric layer 1008. The apparatus 1000 can also include a second mating structure having a second electrode. The second electrode can be the ground layer 1010. When the first and second mating structures are mated to connect the interconnect 1001, the first electrode (the power layer 1006), the thin film dielectric (the first portion 1014 of the third dielectric layer 1008), and the second electrode (the ground layer 1010) form a thin film capacitor, and particularly a decoupling capacitor, between the power channel and the ground channel. The power channel is formed by the power pads, power vias, and power layers. The ground chancel is formed by the ground pads, ground vias, and ground layers. With the architecture of the interconnect 1001, satisfactory noise decoupling can be achieved.

In one or more other examples, the interconnect 1001 of the apparatus 1000 can include a first mating structure that includes a first electrode and a thin film dielectric disposed on the first electrode. For the apparatus 1000, the first electrode can be the ground layer 1010 and the thin film dielectric can be the first portion 1014 of the third dielectric layer 1008. The apparatus 1000 can also include a second mating structure having a second electrode. The second electrode can be the power layer 1006. When the first and second mating structures are mated to connect the interconnect 1001, the first electrode (the ground layer 1010), the thin film dielectric (the first portion 1014 of the third dielectric layer 1008), and the second electrode (the power layer 1006) form a thin film capacitor, and particularly a decoupling capacitor, between the power channel and the ground channel.

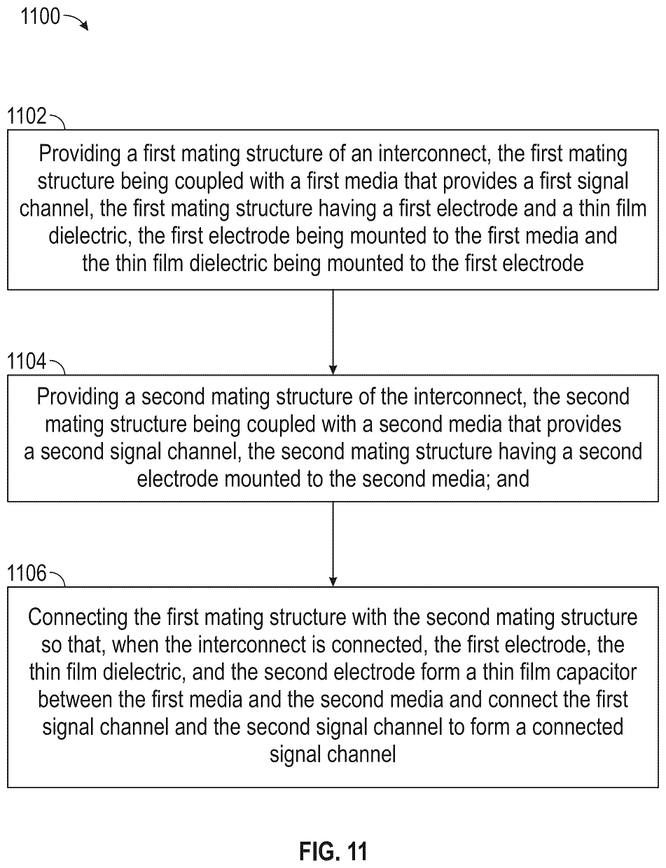

FIG. 11 provides a flow diagram for a method 1100 of assembling an apparatus having at least one interconnect.

At 1102, the method 1100 can include providing a first mating structure of an interconnect, the first mating structure being coupled with a first media that provides a first signal channel, the first mating structure having a first electrode and a thin film dielectric, the first electrode being mounted to the first media and the thin film dielectric being mounted to the first electrode. In one or more example implementations, in providing the first mating structure at 1102, the first mating structure can further include a thin conductive layer mounted to the thin film dielectric such that the first electrode and the thin conductive layer sandwich the thin film dielectric therebetween. The first electrode can be arranged as a pad (e.g., a rectangular pad), and the thin film dielectric can be deposited thereon on with a predetermined thickness, e.g., to achieve a predetermined capacitance of the thin film capacitor to be formed at 1106.

At 1104, the method 1100 can include providing a second mating structure of the interconnect, the second mating structure being coupled with a second media that provides a second signal channel, the second mating structure having a second electrode mounted to the second media. The second electrode can be arranged as a pad (e.g., a rectangular pad) and shaped complementary to the first electrode and thin film dielectric disposed thereon. In one or more implementations, a thin film dielectric can also be deposited on the second electrode.

At 1106, the method 1100 can include connecting the first mating structure with the second mating structure so that, when the interconnect is connected, the first electrode, the thin film dielectric, and the second electrode form a thin film capacitor between the first media and the second media and connect the first signal channel and the second signal channel to form a connected signal channel, e.g., a high-speed electrical signal channel with DC blocking functionality. In some implementations, particularly where a thin film dielectric is deposited on the second electrode, the first electrode, the thin film dielectric disposed on the first electrode, the thin film dielectric disposed on the second electrode, and the second electrode can form the thin film capacitor. The thickness of the thin film dielectric(s) can be selected to achieve a predetermined capacitance, which can in turn provide a desired DC blocking function.

In one or more implementations, the first media is a first PCB and the second media is a second PCB, such as in the example of FIGS. 3A, 3B, 3C, 3D. In some implementations, the first media is a die (e.g., a photonic die) and the second media is a substrate, such as in the example of FIG. 4. In some implementations, the first media is a substrate and the second media is a PCB, such as in the example of FIG. 4. In some implementations, the first media is a first substrate and the second media is a second substrate, such as in the example of FIGS. 5A and 5B. In some implementations, the first media is a PCB and the second media is a twinax cable, such as in the examples of FIG. 6, FIG. 7, FIG. 8. In some implementations, the first media is a first twinax cable and the second media is a second twinax cable, such as in the example of FIGS. 9A, 9B, 9C.

In one or more implementations, the method 1100 can include one or more conductive blocks arranged between the first media and the second media that provide non-capacitive conductive pathways between the first media and the second media. In one or more examples, the conductive blocks can be formed by respective first conductive block structures mounted to the first media and respective second conductive block structures mounted to the second media. The first conductive block structures can each include a first block electrode and a conductive elastomer. The first block electrode can be mounted to the first media and the conductive elastomer can be mounted to the first block electrode. The second conductive block structures can each include a second block electrode. When the first and second block structures are connected, the conductive elastomers can contact or mate with respective ones of the second block electrodes. In or more other examples, the first media or the second media, or both, can include plated pillars that function as the conductive blocks. The conductive blocks and the interconnects can be arranged so that the interconnects and the conductive blocks can connect simultaneously and with low contact force.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. An apparatus, comprising:
a first media providing a first signal channel;
a second media providing a second signal channel; and
an interconnect, comprising:
a first mating structure that includes a first electrode mounted to the first media and a thin film dielectric disposed on the first electrode; and
a second mating structure having a second electrode mounted to the second media,
wherein the first mating structure is connectable with the second mating structure to connect the interconnect so that, when connected, the first electrode, the thin film dielectric, and the second electrode form a thin film capacitor between the first media and the second media and connect the first signal channel and the second signal channel to form a connected signal channel.

2. The apparatus of claim 1, wherein, when the first mating structure is connected with the second mating structure to connect the interconnect, the thin film dielectric contacts the second electrode.

3. The apparatus of claim 2, wherein the thin film dielectric has a contact face that is planar and the second electrode has a contact face that is planar, and wherein, when the first mating structure is connected with the second mating structure to connect the interconnect, the contact face of the thin film dielectric mates with the contact face of the second electrode in a planar face-to-planar face manner.

4. The apparatus of claim 1, wherein the first mating structure has a thin conductive layer mounted to the thin film dielectric opposite the first electrode, and wherein, when the first mating structure is connected with the second mating structure to connect the interconnect, the thin conductive layer contacts the second electrode.

5. The apparatus of claim 1, further comprising:
a conductive block arranged adjacent to the interconnect and having first and second conductive block structures coupled with the first media and the second media, respectively, and wherein, when the first and second conductive block structures are in contact with one another, the conductive block forms a conductive pathway between the first media and the second media.

6. The apparatus of claim 5, wherein the first conductive block structure has a first block electrode, the second conductive block structure has a second block electrode, and wherein a conductive elastomer is mounted to the first block electrode or the second block electrode.

7. The apparatus of claim 6, wherein the first block electrode is mounted to the first media, the second block electrode is mounted to the second media, and when the first mating structure is connected with the second mating structure, the conductive elastomer is arranged between, and in contact with, the first block electrode and the second block electrode.

8. The apparatus of claim 1, further comprising:
a conductive block mounted with the first media or the second media, the conductive block being a plated pillar, and wherein, when the conductive block contacts the first media and the second media, the conductive block forms a conductive pathway between the first media and the second media.

9. The apparatus of claim 1, wherein the interconnect has a third mating structure having a third electrode mounted to the first media, and wherein the thin film dielectric is disposed on the third electrode in addition to the first electrode.

10. The apparatus of claim 9, wherein the second mating structure has a fourth electrode mounted to the second media, and wherein, when the first mating structure is connected with the second mating structure, the thin film dielectric mates with the second electrode and the fourth electrode.

11. The apparatus of claim 1, wherein the first mating structure is removably connectable with the second mating structure.

12. The apparatus of claim 1, wherein the thin film capacitor provides a DC blocking function.

13. The apparatus of claim 1, wherein the first media is a first printed circuit board (PCB) and the second media is a second PCB.

14. The apparatus of claim 1, wherein the first media is a chip substrate and the second media is a printed circuit board (PCB), or vice versa.

15. The apparatus of claim 1, wherein the first media is a first substrate and the second media is a second substrate, or vice versa.

16. The apparatus of claim 1, wherein the first media is a printed circuit board (PCB) and the second media is a multi-connector cable, or vice versa.

17. The apparatus of claim 1, wherein the first media is a first multi-connector cable and the second media is a second multi-connector cable.

18. An apparatus, comprising:
an input dielectric layer having a power input pad and a ground input pad;
an output dielectric layer having a power output pad and a ground output pad; and
a power layer that provides a first electrode;
a ground layer that provides a second electrode;
a dielectric layer having a first portion and a second portion, wherein the first portion has a higher dielectric constant than the second portion;
a power channel having the power layer, the input and output power pads, a first power via, and a second power via, the first power via electrically couples the power input pad with the power layer, and the second power via electrically couples the power layer with the power output pad and also extends through, and is electrically isolated from, the ground layer; and
a ground channel having the ground layer, the input and output ground pads, a first ground via, and a second ground via, the first ground via electrically couples the ground input pad with the ground layer, and the second ground via electrically couples the ground layer with the ground output pad,
wherein the input and output dielectric layers, the dielectric layer, the power layer, and the ground layer are stacked to form an interconnect and so that the dielectric layer is arranged between, and contacts, the first and second electrodes so as to form a decoupling capacitor to decouple the power and ground channels.

19. A method, comprising:
providing a first mating structure of an interconnect, the first mating structure being coupled with a first media that provides a first signal channel, the first mating structure having a first electrode and a thin film dielectric, the first electrode being mounted to the first media and the thin film dielectric being disposed on the first electrode;
providing a second mating structure of the interconnect, the second mating structure being coupled with a second media that provides a second signal channel, the second mating structure having a second electrode mounted to the second media; and
connecting the first mating structure with the second mating structure so that, when the interconnect is connected, the first electrode, the thin film dielectric, and the second electrode form a thin film capacitor between the first media and the second media and connect the first signal channel and the second signal channel to form a connected signal channel.

20. The method of claim 19, further comprising:
simultaneously with connecting the first mating structure and the second mating structure to connect the interconnect, connecting at least one conductive block arranged between the first media and the second media to provide a non-capacitive conductive pathway between the first media and the second media, wherein the at least one conductive block comprises:
a first conductive block structure having a first block electrode and a conductive elastomer, the first block electrode being mounted to the first media and the conductive elastomer being mounted to the first block electrode; and
a second conductive block structure having a second block electrode being mounted to the second media,
wherein when the first conductive block structure and the second conductive block structure are connected, the conductive elastomer contacts the second block electrode.
